(19) United States
(12) Patent Application Publication
(10) Pub. No.: US 2019/0325906 A1
(43) Pub. Date: Oct. 24, 2019

(54) MAGNETIC RECORDING DEVICE WITH GRAPHENE OVERCOAT AND FABRICATION METHOD THEREOF

(71) Applicant: SHOWA DENKO HD TRACE CORPORATION, Hsin-Chu (TW)

(72) Inventors: Moon-Sun Lin, Hsin-Chu (TW); TOMOO SHIGE, Hsin-Chu (TW); Shih-Chin Chen, Hsin-Chu (TW); Yu-Lun Chueh, Hsin-Chu (TW); Li-Chia Yang, Hsin-Chu (TW); Yu-Ze Chen, Hsin-Chu (TW); Yao-Jen Kuo, Hsin-Chu (TW)

(21) Appl. No.: 16/459,629

(22) Filed: Jul. 2, 2019

(30) Foreign Application Priority Data
Jan. 10, 2019 (TW) 108100954

(51) Int. Cl. G11B 5/725; G11B 5/667; G11B 5/84

(52) U.S. Cl. CPC G11B 5/725; C23C 16/27; G11B 5/8408; G11B 5/667

(57) ABSTRACT

A magnetic recording device includes a substrate, an intermediate layer disposed on the substrate, a magnetic recording layer disposed on the intermediate layer, and a graphene overcoat disposed on the magnetic recording layer. The graphene overcoat includes at least one layer of a graphene monoatomic layer which is a sheet-like monoatomic layer of sp2 bonded carbon atoms. A transition layer is interposed between the graphene overcoat and the magnetic recording layer. The transition layer includes carbon and at least one metal of the magnetic recording layer.

### BACKGROUND OF THE INVENTION

### 1. Field of the Invention

The present invention relates to the field of magnetic recording technology, and more particularly to a magnetic recording device having a graphene overcoat and a method of fabricating the same.

### 2. Description of the Prior Art

A hard-disk drive (HDD) is a non-volatile storage device that magnetically records information on a computer. It usually consists of several high-speed rotating platters and a read/write head placed on the actuator arm. By using a magnetic head that is in extremely close proximity to the magnetic surface, the information can be written to the disc by changing the polarity of the electromagnetic current. In the opposite way, for example, when the magnetic head passes over the recorded data, the magnetic field causes a change in the electrical signal in the coil such that the data can be read.

It is known that to improve the read/write performance of the head/platter, in addition to the alloy design of the magnetic recording layer in the platter, the reduction of the head flying height is one of the key techniques to achieve ultra-high areal recording density of the hard disk drive. One of the key technologies for ultra-high magnetic recording density. The head flying height refers to the distance from the head to the upper surface of the magnetic recording layer, which usually includes the thickness of a diamond-like carbon (DLC) film. The DLC film is a high-hardness amorphous carbon (α-C) layer formed by plasma-assisted vapor deposition (PECVD) to protect the magnetic recording layer in the platter, which provides corrosion resistance and other features such as tribology.

Many studies have been focused on the improvements of the DLC film to thereby reducing the thickness of the DLC film so as to enhance read and write characteristics and recording density. However, when the thickness of the DLC film is reduced to less than or equal to 2 nanometers (nm), the abrasion and corrosion durability of such thin DLC film will become problematic. Therefore, there is still a need in the art for an improved magnetic recording component and method of fabrication to address the deficiencies and shortcomings of the prior art.

### SUMMARY OF THE INVENTION

It is one object of the present invention to provide an improved magnetic recording device having a graphene overcoat of a single atom thickness, which can effectively protect the magnetic recording layer in the platter and reduce the head flying height in the hard disk drive.

Another object of the present invention is to provide a method for fabricating a magnetic recording device having a graphene overcoat, which only needs to add a laser process in the conventional fabrication process of the magnetic recording device, and which has the advantages of low cost, suitability of industrial grade mass production and applications.

According to an embodiment of the invention, a magnetic recording device includes a substrate; an intermediate layer disposed on the substrate; a magnetic recording layer disposed on the intermediate layer; and a graphene overcoat disposed on the magnetic recording layer. The graphene overcoat comprises at least one layer of a graphene monoatomic layer which is a sheet-like monoatomic layer of sp2 bonded carbon atoms. A transition layer is disposed between the graphene overcoat and the magnetic recording layer. The transition layer comprises carbon and at least one metal of the magnetic recording layer.

Another aspect of the invention discloses a method of fabricating a magnetic recording device, comprising: providing a laminated structure comprising a substrate, an intermediate layer, a magnetic recording layer, and a diamond-like carbon film; placing the laminated structure in a hermetic vacuum chamber and vacuumizing the vacuum chamber; irradiating and heating a predetermined area of the diamond-like carbon film by a laser beam; and moving the laser beam away from the predetermined area so that a graphene overcoat precipitates on the upper surface of the magnetic recording layer. Finally, the laminated structure is taken out from the chamber, and a lubricant layer is formed on the upper surface of the graphene overcoat. The laser beam provides a sufficient energy that exceeds an energy conversion barrier to temporarily dissolve carbon atoms of the diamond-like carbon film into the surface layer of the magnetic recording layer in the region irradiated by the laser beam.

According to an embodiment of the invention, a pressure in the vacuum chamber is less than 10⁻⁴ mbar. The laser beam is a continuous wave laser having a wavelength of 808 nm. The intensity of the laser beam is less than or equal to 0.1 W/mm².

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIG. 1 is a schematic cross-sectional diagram showing a magnetic recording device according to an embodiment of the invention.

FIG. 2 to FIG. 5 are schematic cross-sectional views showing a method of fabricating a magnetic recording device according to an embodiment of the invention.

### DETAILED DESCRIPTION

In the following detailed description of the disclosure, reference is made to the accompanying drawings, which form a part hereof, and in which is shown, by way of illustration, specific embodiments in which the invention may be practiced. These embodiments are described in sufficient detail to enable those skilled in the art to practice the invention. Other embodiments may be utilized and structural, logical, and electrical changes may be made without departing from the scope of the present invention. Therefore, the following detailed description is not to be considered as limiting, but the embodiments included herein are defined by the scope of the accompanying claims.

The present invention relates to an improved magnetic recording device having a graphene overcoat of a monoatomic thickness, which continuously and completely covers the entire upper surface of the magnetic recording layer in the platter. The graphene overcoat effectively protects the magnetic recording layer in the platter and reduces the head flying height of the head/platter in the hard disk drive. Another aspect of the present invention provides a method for fabricating a magnetic recording device having a graphene overcoat, which can form a graphene directly on the surface of the magnetic recording layer by only adding a laser irradiation process to the original fabrication process of the magnetic recording device. The disclosed method can be compatible with the current fabrication process of the magnetic recording device without affecting the characteristics of the magnetic recording layer thereof, which has the advantages of low cost and is easy to scale up to industrial scale mass production and application.

Currently, the magnetic recording technology used in hard disks is mainly divided into two types: Perpendicular Magnetic Recording (PMR) and Shingled Magnetic Recording (SMR). Heat Assisted Magnetic Recording (HAMR) is a promising next-generation technology when facing the challenge of physical limit when enhancing magnetic recording density. HARM technology uses laser heating to make the unit area where the platter can produce magnetism smaller, because increasing the temperature can reduce the critical size of the superparamagnetism of the magnetic particles, thereby improving the read/write density of the platter in unit area. HARM technology was first proposed by Fujitsu in 2006, and it usually uses a highly magnetically stable material such as platinum-iron alloy.

A read/write head is an important component of a hard disk drive that moves over a disk platter and converts the magnetic field into a current (for reading), or vice versa, converting the current into a magnetic field (for writing). Hereinafter, the terms “head flying height”, “floating height” or “head/platter read/write gap” refers to the distance from the head on the hard disk to the surface of the magnetic recording layer in the platter. Hereinafter, the term “graphene” means a two-dimensional honeycomb crystal lattice structure consisting of sp2 bonded carbon atoms, which has a thickness of only one carbon atom. The term “multilayer graphene” is a layered structure in which sheets of graphene are stacked and bonded to each other through Van der Waals force.

Conventionally, graphene can be produced by mechanical exfoliation or chemical vapor deposition (CVD) methods. However, it is difficult to control the size and thickness of graphene when produced by mechanical exfoliation, and CVD methods require a high temperature exceeding 1000 degrees Celsius and have contamination problem when transferring graphene. Therefore, the conventional methods of producing graphene is not suitable for mass production of magnetic recording devices, and the cost is too high. The present invention can solve the deficiencies and shortcomings of the prior art.

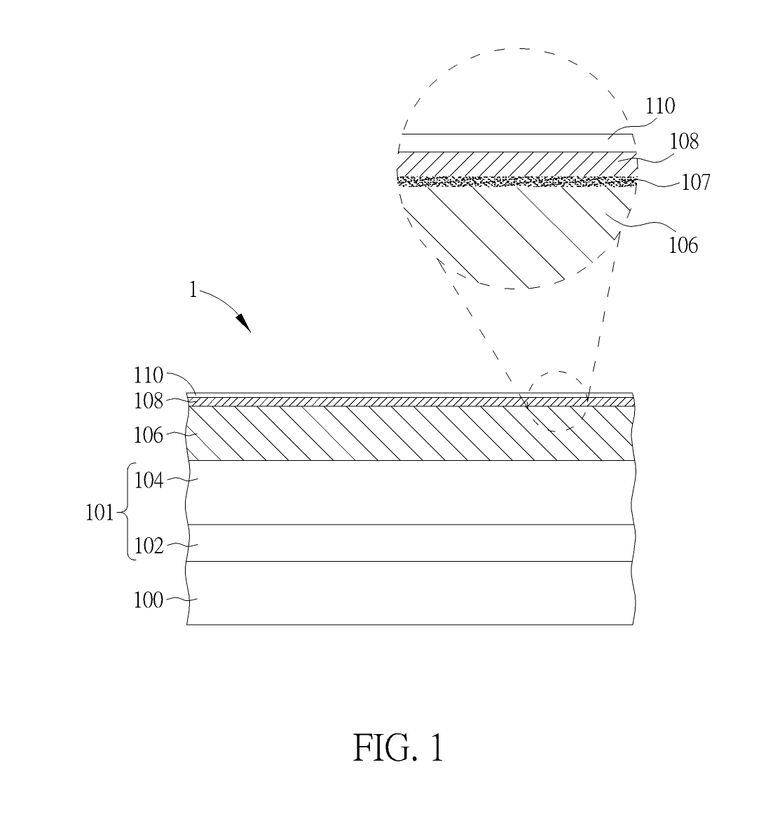

Please refer to FIG. 1, which is a cross-sectional view of a magnetic recording device according to an embodiment of the invention. As shown in FIG. 1, the magnetic recording device 1 comprises a substrate 100, for example, a glass substrate, an aluminum substrate, an aluminum alloy substrate, or an aluminum-magnesium alloy substrate, but is not limited thereto. An intermediate layer 101, a magnetic recording layer 106, and a graphene overcoat 108 are sequentially disposed on the substrate 100. In some embodiments, a lubricant layer 110 may be disposed on the graphene overcoat 108. In some embodiments, the intermediate layer 101 may comprise a bottom layer 102 and an interface layer 104, but is not limited thereto. For example, the bottom layer 102 may be composed of a soft magnetic material, but is not limited thereto. The interface layer 104 may include, but is not limited to, Co, Pt, Cr, Ru, Ti, TiN, Ni, Ag, any combination thereof, or alloys thereof. In some embodiments, the intermediate layer 101 may further comprise a seed layer.

According to an embodiment of the present invention, the intermediate layer 101 is provided for causing the magnetic recording layer 106 to have the columnar crystal structure with c-axis orientation, and the intermediate layer 101 may be composed of Ru or a Ru alloy. The aforesaid Ru alloy may be, for example, RuCo, RuAl, RuMn, RuMo, RuFe alloy, but is not limited thereto. For example, the Ru content in the Ru alloy may be between 50 at. % and 90 at. %. For example, the intermediate layer 101 may have a film thickness of about 30 nm or less. The magnetic recording layer 106 may be composed of a magnetic film having an axis of easy magnetization toward a direction perpendicular to the main surface of the substrate 100 (perpendicular magnetic recording layer). For example, the magnetic recording layer 106 may contain Co, Pt, or an alloy thereof, but is not limited thereto. Further, an oxide or elements such as Cr, B, Cu, Ta, Zr, Ru, or the like may be added to the magnetic recording layer 106. Example of the oxide may include, for example, SiO₂, SiO, Cr₂O₃, CoO, Co₃O₄, Ta₂O₃, TiO₂, B₂O₃, or the like.

According to another embodiment of the present invention, the intermediate layer 101 may comprise Cr, Ru or an alloy thereof. The magnetic recording layer 106 may comprise Fe, Pt, Ni, or an alloy thereof, but is not limited thereto. For example, the magnetic recording layer 106 may be a granular structure in which magnetic crystal grains are separated by grain boundaries of SiO₂. Further, TiO₂, Al₂O₃, Ta₂O₅, ZrO₂, MnO, TiO, ZnO or a combination thereof may be used as a grain boundary phase.

According to an embodiment of the present invention, the graphene overcoat 108 may comprise at least one layer of a graphene monoatomic layer which is a sheet-like monoatomic layer of sp2 bonded carbon atoms. For example, the graphene overcoat 108 may comprise 1 to 10 layers of graphene monoatomic layers. For example, preferably, the graphene overcoat 108 may comprise 1 to 5 layers of graphene monoatomic layers, preferably 1 to 2 layers of graphene monoatomic layers. According to an embodiment of the invention, a single layer of graphene monoatomic layer is taken as an example, and its coefficient of friction may be less than about 0.2.

According to an embodiment of the invention, the single layer of graphene monoatomic layer has a thickness of about 0.345 nm. According to an embodiment of the invention, in a case that the graphene overcoat 108 is composed of two or more layers of graphene monoatomic layers, the spacing between the two adjacent graphene monoatomic layers may be about 0.345 nm, but is not limited thereto. this. According to an embodiment of the invention, the graphene overcoat 108 has a thickness of less than or equal to 2 nm. According to another embodiment of the invention, the thickness of the graphene overcoat 108 is less than or equal to 1.5 nm. According to still another embodiment of the present invention, the graphene overcoat 108 has a thickness of less than or equal to 1.0 nm.

According to an embodiment of the present invention, the graphene overcoat 108 continuously and completely covers the upper surface of the magnetic recording layer 106. According to an embodiment of the present invention, as shown in the enlarged view on the right side of FIG. 1, a transition layer 107 may be formed between the graphene overcoat 108 and the magnetic recording layer 106, for example, an alloy layer doped with a small amount of carbon atoms, such as, a composite layer of Co/Pt/Cr/C in which the content of carbon atoms is less than 0.6 at. %. The transition layer 107 can enhance the adhesion between the graphene overcoat 108 and the magnetic recording layer 106. According to an embodiment of the invention, the thickness of the transition layer 107 is less than or equal to 1.0 nm. According to an embodiment of the invention, the thickness of the transition layer 107 is less than or equal to 0.5 nm. It is noteworthy that, according to the embodiment of the present invention, there is no need to form any nucleation layer or capping layer between the graphene overcoat 108 and the magnetic recording layer 106, which makes the head flying height smaller.

According to an embodiment of the invention, the lubricant layer 110 may be formed on the graphene overcoat 108. For example, the lubricant layer 110 may comprise perfluoropolyether or the like. According to an embodiment of the invention, the lubricant layer 110 has a thickness of about 1 nm. According to another embodiment of the invention, the thickness of the lubricant layer 110 is less than 1 nm.

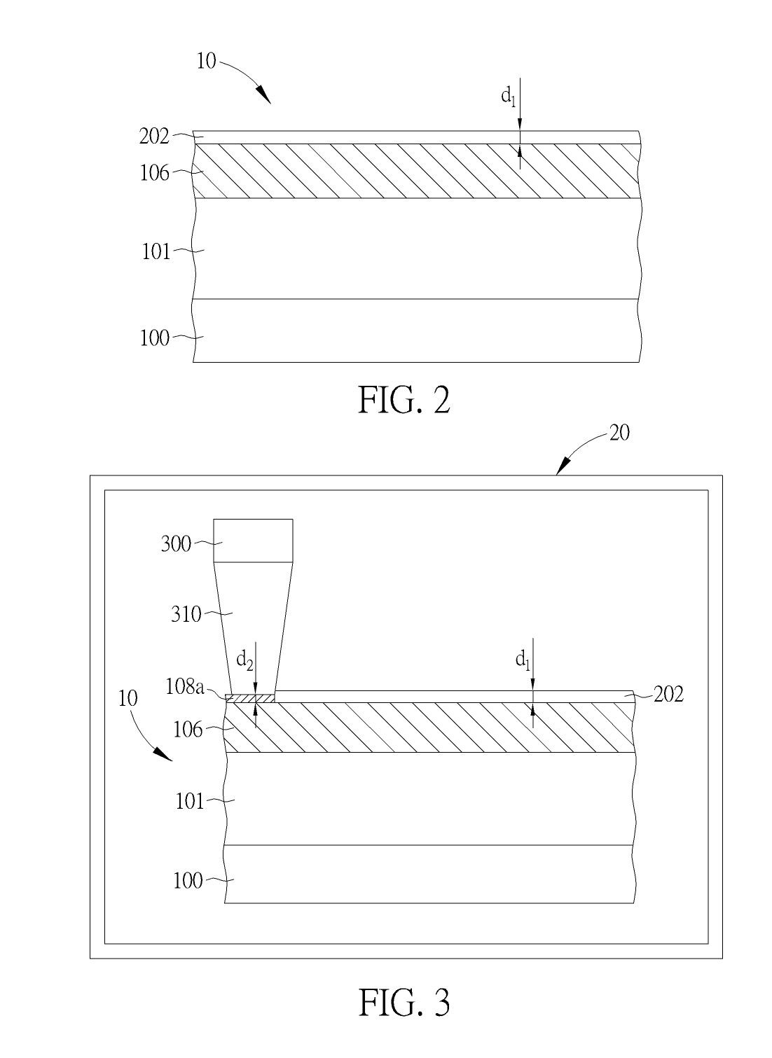

FIG. 2 to FIG. 5 are schematic cross-sectional views showing a method of fabricating a magnetic recording device according to an embodiment of the invention, wherein the same regions, layers or elements are still denoted by the same reference numerals. As shown in FIG. 2, a laminated structure 10 is provided comprising a substrate 100, an intermediate layer 101, a magnetic recording layer 106, and a diamond-like carbon film 202. According to an embodiment of the present invention, the substrate 100 may be, for example, a glass substrate, an aluminum substrate, an aluminum alloy substrate, or an aluminum-magnesium alloy substrate, but is not limited thereto.

According to an embodiment of the present invention, the intermediate layer 101 is provided for causing the magnetic recording layer 106 to have the columnar crystal structure with c-axis orientation, and the intermediate layer 101 may be composed of Ru or a Ru alloy. The aforesaid Ru alloy may be, for example, RuCo, RuAl, RuMn, RuMo, RuFe alloy, but is not limited thereto. For example, the Ru content in the Ru alloy may be between 50 at. % and 90 at. %. For example, the intermediate layer 101 may have a film thickness of about 30 nm or less. The magnetic recording layer 106 may be composed of a magnetic film having an axis of easy magnetization toward a direction perpendicular to the main surface of the substrate 100 (perpendicular magnetic recording layer). For example, the magnetic recording layer 106 may contain Co, Pt, or an alloy thereof, but is not limited thereto. Further, an oxide or elements such as Cr, B, Cu, Ta, Zr, Ru, or the like may be added to the magnetic recording layer 106. Example of the oxide may include, for example, SiO₂, SiO, Cr₂O₃, CoO, Co₃O₄, Ta₂O₃, TiO₂, B₂O₃, or the like.

According to another embodiment of the present invention, the intermediate layer 101 may comprise Cr, Ru or an alloy thereof. The magnetic recording layer 106 may comprise Fe, Pt, Ni, or an alloy thereof, but is not limited thereto. For example, the magnetic recording layer 106 may be a granular structure in which magnetic crystal grains are separated by grain boundaries of SiO₂. Further, TiO₂, Al₂O₃, Ta₂O₅, ZrO₂, MnO, TiO, ZnO or a combination thereof may be used as a grain boundary phase.

According to an embodiment of the present invention, the diamond-like carbon film 202 may be formed by plasma assisted vapor deposition (PECVD), but is not limited thereto. In other embodiments, the diamond-like carbon film 202 can be formed using different methods, such as sputtering. According to an embodiment of the invention, the diamond-like carbon film 202 has a thickness d₁, wherein the thickness d₁ may be between 0.5 nm and 5.0 nm. According to another embodiment of the invention, the thickness d₁ may be between 1.0 nm and 3.0 nm. According to an embodiment of the invention, the diamond-like carbon film 202 directly contacts the upper surface of the magnetic recording layer 106.

As shown in FIG. 3, the laminated structure 10 is then placed in a hermetic vacuum chamber 20 and the vacuum chamber 20 is evacuated to vacuum, for example, to a vacuum degree of less than 10⁻⁴ mbar. Then, the diamond-like carbon film 202 is struck by a laser beam 310 via a laser source 300 in the vacuum environment described above. According to an embodiment of the invention, the laser beam 310 may be a continuous wave laser whose wavelength may be, for example, 808 nm, but is not limited thereto. In other embodiments, a pulsed laser can also be employed.

According to an embodiment of the invention, the intensity of the laser beam 310 may be less than or equal to 0.1 W/mm². Under this condition, the laser beam 310 can provide sufficient energy to exceed the energy conversion barrier, temporarily dissolving the carbon atoms of the diamond-like carbon film 202 into the surface layer of the magnetic recording layer 106 within the region irradiated by the laser beam 310. When the laser beam 310 is subsequently moved to other areas, the originally irradiated area is cooled, so that carbon atoms dissolved in the surface layer of the magnetic recording layer 106 are precipitated on the upper surface of the magnetic recording layer 106, forming a partial graphene overcoat 108a comprising one or more layers of graphene monoatomic layers.

According to an embodiment of the invention, the partial graphene overcoat 108a has a thickness d₂, wherein the thickness d₂ is smaller than the thickness d₁ of the diamond-like carbon film 202. According to an embodiment of the invention, the thickness d₂ is less than or equal to 2 nm.

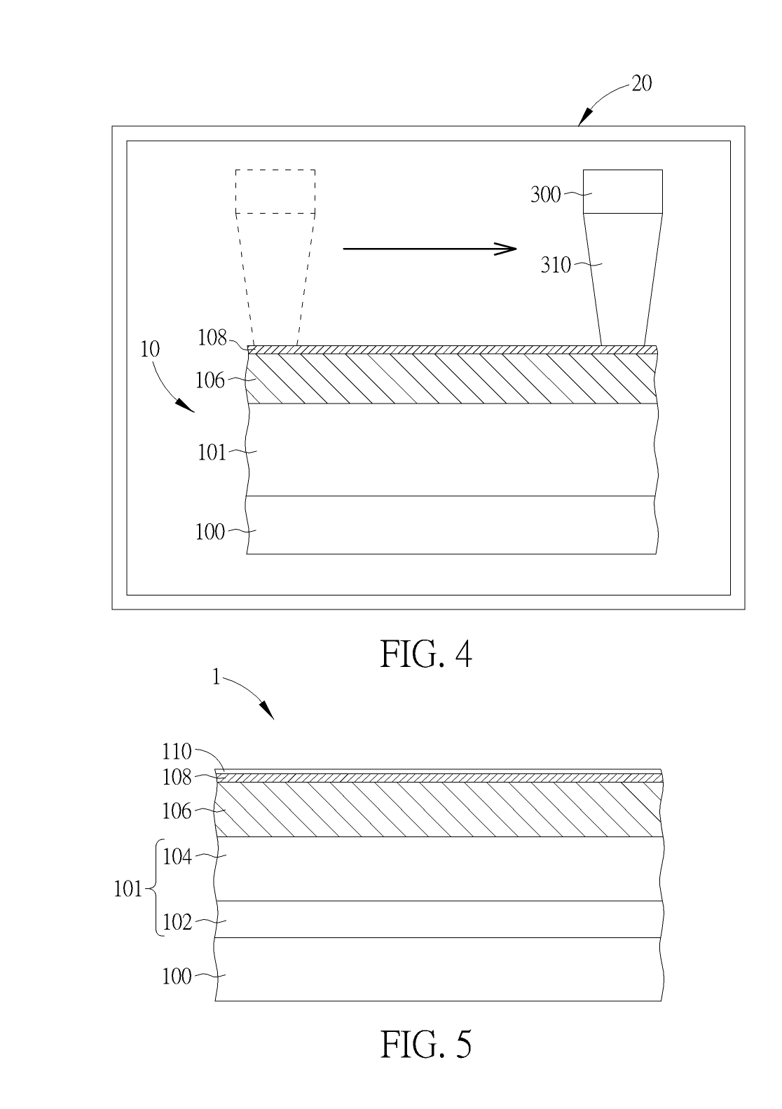

As shown in FIG. 4, by sequentially scanning the laser beam 310 to illuminate the diamond-like carbon film 202, a large-area and high-quality graphene overcoat 108 is formed on the upper surface of the magnetic recording layer 106, which continuously and completely covers the upper surface of the magnetic recording layer 106. According to an embodiment of the present invention, as shown in the enlarged view on the right side of FIG. 1, a transition layer 107 may be formed between the graphene overcoat 108 and the magnetic recording layer 106, for example, an alloy layer doped with a small amount of carbon atoms. For example, a composite layer of Co/Pt/Cr/C in which the content of carbon atoms is less than 0.6 at. %, and the transition layer 107 can enhance the adhesion between the graphene overcoat 108 and the magnetic recording layer 106. The aforementioned laser-induced graphene growth process may include different stages such as laser heating-carbon dissolution-cooling-carbon precipitation-sp2 bonding.

Since the metals such as Co or Fe in the surface layer of the magnetic recording layer 106 act as a catalyst to lower the energy conversion barrier, the present invention can employ a low-intensity (less than or equal to 0.1 W/mm²) laser beam. The carbon atoms of the diamond-like carbon film 202 in the region irradiated by the low-intensity laser beam 310 are dissolved in the surface layer of the magnetic recording layer 106 at relatively low temperatures, wherein the local temperature in the region irradiated by the laser beam 310 can be controlled below 500° C. or even below 200° C., so the magnetic characteristics of the magnetic recording layer 106 are not affected. In addition, the vacuum environment also plays a key role because it has been found through experiments that no graphene overcoat 108 is formed on the upper surface of the magnetic recording layer 106 unless vacuum is applied.

From the experimental results, even though the same procedure as described above was carried out under a nitrogen atmosphere of 10⁻² mbar, the signal of graphene was not found by Raman spectroscopy, and therefore the applicant believes that the pressure should be an important factor.

As shown in FIG. 5, after the entire upper surface of the magnetic recording layer 106 is completely scanned by the laser beam 310, a large-area and high-quality graphene overcoat 108 is formed, which continuously and completely covers the upper surface of the magnetic recording layer 106.

The graphene overcoat 108 may comprise at least one layer of a graphene monoatomic layer which is a sheet-like monoatomic layer of sp2 bonded carbon atoms. For example, the graphene overcoat 108 may contain 1 to 10 layers of graphene monoatomic layers. For example, preferably, the graphene overcoat 108 may comprise 1 to 5 layers of graphene monoatomic layers, preferably 1 to 2 layers of graphene monoatomic layers. According to an embodiment of the invention, a single layer of graphene monoatomic layer is taken as an example, and the coefficient of friction thereof may be less than about 0.2.

According to an embodiment of the invention, the single layer of graphene monoatomic layer has a thickness of about 0.345 nm. According to an embodiment of the invention, in a case that the graphene overcoat 108 is composed of two or more layers of graphene monoatoms, the spacing between the adjacent graphene monoatomic layers may be about 0.345 nm, but is not limited thereto. According to an embodiment of the invention, the graphene overcoat 108 has a thickness of less than or equal to 2 nm. According to another embodiment of the invention, the thickness of the graphene overcoat 108 is less than or equal to 1.5 nm. According to still another embodiment of the present invention, the graphene overcoat 108 has a thickness of less than or equal to 1.0 nm.

Subsequently, the laminated structure 10 is taken out from the vacuum chamber 20, and a lubricant layer 110 composed of, for example, perfluoropolyether or the like, is formed on the upper surface of the graphene overcoat 108, and the magnetic recording device 1 is completed.

Structurally, as shown in FIG. 1, the magnetic recording device 1 includes a substrate 100, an intermediate layer 101 disposed on the substrate 100, a magnetic recording layer 106 disposed on the intermediate layer 101, a graphene overcoat 108 disposed on the magnetic recording layer 106, and a transition layer 107 disposed between the graphene overcoat 108 and the magnetic recording layer 106. The transition layer 107 comprises carbon and at least one metal of the magnetic recording layer 108.

Those skilled in the art will readily observe that numerous modifications and alterations of the device and method may be made while retaining the teachings of the invention. Accordingly, the above disclosure should be construed as limited only by the metes and bounds of the appended claims.

What is claimed is:

1. A magnetic recording device, comprising:
a substrate;
an intermediate layer disposed on the substrate;
a magnetic recording layer disposed on the intermediate layer;
a graphene overcoat disposed on the magnetic recording layer, wherein the graphene overcoat comprises at least one layer of a graphene monoatomic layer which is a sheet-like monoatomic layer of sp2 bonded carbon atoms; and
a transition layer disposed between the graphene overcoat and the magnetic recording layer, wherein the transition layer comprises carbon and at least one metal of the magnetic recording layer, and wherein the transition layer directly contacts the graphene overcoat, and the transition layer directly contacts the magnetic recording layer.

2. The magnetic recording device according to claim 1, wherein the intermediate layer comprises a bottom layer and an interface layer.

3. The magnetic recording device according to claim 2, wherein the bottom layer is composed of a soft magnetic material.

4. The magnetic recording device according to claim 2, wherein the interface layer comprises Co, Pt, Cr, Ru, Ti, TiN, Ni, Ag, any combination thereof or alloy thereof.

5. The magnetic recording device according to claim 1, wherein the intermediate layer comprises Ru or a Ru alloy, and the magnetic recording layer comprises Co, Pt or an alloy thereof.

6. The magnetic recording device according to claim 1, wherein the intermediate layer comprises Cr, Ru or an alloy thereof, and the magnetic recording layer comprises Fe, Pt, Ni or an alloy thereof.

7. The magnetic recording device according to claim 1, wherein the graphene overcoat comprises 1 to 5 layers of the graphene monoatomic layer.

8. The magnetic recording device according to claim 7, wherein a spacing between the graphene monoatomic layers is approximately 0.353 nm.

9. The magnetic recording device according to claim 1, wherein a thickness of the graphene overcoat is less than or equal to 2 nm.

10. The magnetic recording device according to claim 1 further comprising:
a lubricant layer disposed on the graphene overcoat.

11. A method for forming a magnetic recording device, comprising:
providing a laminated structure comprising a substrate, an intermediate layer, a magnetic recording layer, and a diamond-like carbon film;
placing the laminated structure in a hermetic vacuum chamber and vacuumizing the vacuum chamber;
irradiating and heating a predetermined area of the diamond-like carbon film by a laser beam; and
moving the laser beam away from the predetermined area so that a graphene overcoat precipitates on an upper surface of the magnetic recording layer.

12. The method according to claim 11, wherein the diamond-like carbon film is formed by a plasma assisted vapor deposition (PECVD) process.

13. The method according to claim 11, wherein the diamond-like carbon film has a first thickness, wherein the first thickness is between 0.5 nm and 5 nm.

14. The method according to claim 13, wherein the graphene overcoat has a second thickness, wherein the second thickness is less than the first thickness.

15. The method according to claim 14, wherein the second thickness is less than or equal to 2 nm.

16. The method according to claim 11, wherein a vacuum degree in the vacuum chamber is less than 10⁻⁴ mbar.

17. The method according to claim 11, wherein the laser beam is a continuous wave laser having a wavelength of 808 nm.

18. The method according to claim 17, wherein an intensity of the laser beam is less than or equal to 0.1 W/mm².

19. The method according to claim 11, wherein the laser beam provides a sufficient energy to exceed an energy conversion barrier to temporarily dissolve carbon atoms of the diamond-like carbon film in a region irradiated by the laser beam into a surface layer of the magnetic recording layer.

20. The method according to claim 11 further comprising:
taking the laminated structure out from the vacuum chamber, and then forming a lubricant layer on an upper surface of the graphene overcoat.
